(19) United States
(12) Patent Application Publication
(10) Pub. No.: US 2013/0328014 A1
(43) Pub. Date: Dec. 12, 2013

(54) GAAS/INGAAS AXIAL HETEROSTRUCTURE FORMATION IN NANOPILLARS BY CATALYST-FREE SELECTIVE AREA MOCVD

(71) Applicants: Joshua Shapiro, Los Angeles, CA (US); Diana Huffaker, Los Angeles, CA (US)

(72) Inventors: Joshua Shapiro, Los Angeles, CA (US); Diana Huffaker, Los Angeles, CA (US)

(73) Assignee: The Regents of the University of California, Oakland, CA (US)

(21) Appl. No.: 14/002,078

(22) PCT Filed: Mar. 1, 2012
(86) PCT No.: PCT/US2012/027295

§ 371 Date: Aug. 28, 2013

Related U.S. Application Data
(60) Provisional application No. 61/448,017, filed on Mar. 1, 2011.

(51) Int. Cl. H01L 29/66; H01L 21/02

(52) U.S. Cl. CPC H01L 29/66977; H01L 21/02634; B82Y 99/00
USPC 257/14; 438/478; 977/762

(57) ABSTRACT

An axially hetero-structured nanowire includes a first segment that includes GaAs, and a second segment integral with the first that includes InₓGa₁₋ₓAs. The parameter x has a maximum value x-max within the second segment that is at least 0.02 and less than 0.5. A nanostructured semiconductor component includes a GaAs (111)B substrate, and a plurality of nanopillars integral with the substrate at an end thereof. Each of the plurality of nanopillars can be a nanowire according to an embodiment of the current invention. A method of producing axially hetero-structured nanowires is also provided.

### CROSS-REFERENCE OF RELATED APPLICATION

This application claims priority to U.S. Provisional Application No. 61/448,017 filed Mar. 1, 2011, the entire contents of which are hereby incorporated by reference.

This invention was made with Government support under Grant Nos. 0824273, 0903720, and 1007051, awarded by the National Science Foundation and Grant Nos. FA9550-08-1-0198 and FA9550-09-1-0270, awarded by the U.S. Air Force, Air Force Office of Scientific Research. The U.S. Government has certain rights in this invention.

### BACKGROUND

1. Field of Invention

The field of the currently claimed embodiments of this invention relates to nanowires, and more particularly to axially heterostructured nanowires.

2. Discussion of Related Art

With continued maturity of self-assembled synthesis processes, nanowires (NWs) are the subject of extensive studies in many semiconductor material systems for their small size, large surface to volume ratio and applications in a large variety of devices. Nanowire-based device demonstrations include photovoltaics (Giacomo Mariani, Ramesh B. Laghumavarapu, Bertrand Tremolet de Villers, Joshua Shapiro, Pradeep Senanayake, Andrew Lin, Benjamin J. Schwartz, and Diana L. Huffaker, Appl. Phys. Lett., 97, 013107 (2010)), high speed transistors (Shadi A. Dayeh, David P. R. Aplin, Xiaotian Zhou, Paul K. L. Yu, Edward T. Yu, and Deli Wang, Small, 3, 2 (2006)), high sensitivity detectors (C. Soci, A. Zhang, B. Xiang, S. A. Dayeh, D. P. R. Aplin, J. Park, X. Y. Bao, Y. H. Lo, and D. Wang, Nano Lett., 7, 4 (2007)) and new types of emitters (S. D. Hersee, M. Fairchild, A. K. Rishinaramangalam, M. S. Ferdous, L. Zhang, P. M. Varangis, B. S. Swartzentruber, and A. A. Talin, Elect. Lett., 45, 1 (2009); Fang Qian, Yat Li, Silvija Gradeak, Deli Wang, Carl J. Barrelet, and Charles M. Lieber, Nano Letters, 4, 10 (2004)). The conventional formation method is the vapor-liquid-solid (VLS) technique in which a metal catalyst enhances adatom incorporation at the catalyst/semiconductor interface to promote vertical growth. While the VLS technique allows for flexibility in material choices, the NW dimensions; location and crystallographic orientation are difficult to control. Furthermore, there is typically contamination from the catalysts (Daniel E. Perea, Jonathan E. Allen, Steven J. May, Bruce W. Wessels, David N. Seidman, and Lincoln J. Lauhon, Nano Lett., 6, 2 (2006)) that can lead to leakage current in III-V NW-based devices (K. Haraguchi, K. Hiruma, T. Katsuyama, T. Shimada, Curr. Appl. Phys., 6, 1, (2006)).

Patterned nanopillar (NP) formation by selective area epitaxy (SAE) offers a catalyst-free approach that avoids contamination and more importantly, offers the ability to grow large arrays of pillars with lithographically-defined diameters and locations (Motohisa, J. and Noborisaka, J. and Takeda, J. and Inari, M. and Fukui, T., J. Cryst. Growth 272, 1-4 (2004)). In addition, the patterning process permits optical alignment marks for device integration. However, in the absence of a growth catalyst to promote vertical growth, adatom incorporation is determined by diffusion lengths and binding energies. The crystal shape is determined by the relative surface energies of the crystal planes (Keitaro Ikejiri, Takuya Sato, Hiroatsu Yoshida, Kenji Hiruma, Junichi Motohisa, Shinjiroh Hara, and Takashi Fukui, Nanotechnology, 19, 26 (2008)).

Homoepitaxy of catalyst free NPs has been studied in several III-V binary and ternary materials (Motohisa, et al., id.), however, core-shell and axial heteroepitaxy are in their infancy using this growth mode. Core-shell heterostructures were demonstrated in GaAs/GaAsP (Bin Hua, Junichi Motohisa, Yasunori Kobayashi, Shinjiroh Hara and Takashi Fukui, Nano Lett., 9, 1, (2009)) and GaAs/AlGaAs (Katsuhiro Tomioka, Yasunori Kobayashi, Junichi Motohisa, Shinjiroh Hara and Takashi Fukui, Nanotechnology, 20, 14 (2009)), but axial heterostructures have been elusive. Very thin axial InGaAs double heterostructures were reported in catalyst-free NPs, however, detailed studies of insert characteristics including content, thickness, and interface transitions have not been addressed (L. Yang, J. Motohisa, J. Takeda, K. Tomioka, and T. Fukui, Appl. Phys. Lett., 89, 20 (2006); Lin Yang, Junichi Motohisa, Junichiro Takeda, Katsuhiro Tomioka, and Takashi Fukui, Nanotechnology, 18, 10 (2007); Lin Yang, Junichi Motohisa, Takashi Fukui, Lian X. Jia, Lei Zhang, Ming M. Geng, Pin Chen, and Yu L. Liu, Opt. Exp., 17, 11 (2009)). There thus remains a need for improved methods of producing axially heterostructured nanowires and for the axially heterostructured nanowires produced.

### SUMMARY

An axially hetero-structured nanowire according to an embodiment of the current invention includes a first segment that includes GaAs, and a second segment integral with the first that includes InₓGa₁₋ₓAs. The parameter x has a maximum value x-max within the second segment that is at least 0.02 and less than 0.5.

A nanostructured semiconductor component according to an embodiment of the current invention includes a GaAs (111)B substrate, and a plurality of nanopillars integral with the substrate at an end thereof. Each of the plurality of nanopillars includes a first segment that includes GaAs, and a second segment integral with the first that includes InₓGa₁₋ₓAs. The parameter x has a maximum value x-max within the second segment that is at least 0.02 and less than 0.5.

A catalyst-free, selective-area metal-organic chemical vapor deposition method for producing nanostructures according to an embodiment of the current invention includes providing a GaAs (111)B substrate that includes a patterned layer on a surface thereof to provide exposed regions for epitaxial growth of nanopillars; exposing the substrate to tri-methyl-gallium and tertiary-butyl-arsine for a selected period of time to grow GaAs segments of the nanopillars on the exposed regions; and exposing the substrate and portions of nanopillars grown thereon to tri-methyl-indium, tri-methyl-gallium and tertiary-butyl-arsine for a selected period of time to grow InₓGa₁₋ₓAs segments on the GaAs segments. During the growth of the InₓGa₁₋ₓAs segments, temperatures and pressures of tri-methyl-indium, tri-methyl-gallium and tertiary-butyl-arsine are selected such that the InₓGa₁₋ₓAs segments grow substantially exclusively in an axial direction of the nanopillars. The parameter x has a maximum value x-max within a respective InₓGa₁₋ₓAs segment that is at least 0.02 and less than 0.5.

### BRIEF DESCRIPTION OF THE DRAWINGS

Further objectives and advantages will become apparent from a consideration of the description, drawings, and examples.

FIG. 1A shows SEM side-angle image of a nano-pillar array with axial InGaAs inserts according to an embodiment of the current invention. The inset shows a plan view image of hexagonal NP cross section. FIG. 1B shows HAADF STEM of pillars with 90 s InGaAs inserts and (FIG. 1C) 3×60 s InGaAs inserts.

FIG. 2 show HAADF STEM, In content (solid) measured by EDS, and growth time (dashed) with (FIG. 2A) 3×60 s InGaAs inserts and (FIG. 2B) 90 s insert. Insets: High resolution HAADF STEM and EDS revealing the In content variation along a single InGaAs insert indicated by a dashed box.

FIG. 3 shows vertical growth rate versus position. Markers show average growth rate for each GaAs section in a sample. The dashed line is a linear least-squares fit to data.

FIG. 4A shows 77K PL spectra of 180 s, 90 s and 3×60 s samples. FIG. 4B shows temperature dependent NP PL wavelength from 180 s, 90 s and 3×60 s samples. Solid lines are second order polynomial fits to the measured data.

FIG. 5A is an SEM of GaAs nanopillars containing axial InGaAs inserts grown at high VIII ratio according to an embodiment of the current invention. FIG. 5B shows dark-field STEM of a single InGaAs insert according to an embodiment of the current invention. FIG. 5C shows SEM of GaAs nanopillars terminated with InGaAs at low VIII ratio.

FIG. 6 shows surface reconstructions/relaxations of the GaAs (111)A and (110) surfaces. Top left: the (111)A Ga vacancy surface. Top right: the (111)A As trimer surface. Bottom left: the (110) Ga—As chain surface. Bottom right: the (110)As—As chain surface. Arsenic atoms are light gray spheres and gallium atoms are dark gray spheres. Top and side views are rendered with two or three layers of atoms. The atomic diameters are drawn larger for atoms closer to the surface. The unit cell is identified by a shaded parallelogram or rectangle.

FIGS. 7A and 7B is a Potential energy surface for Ga and In adatoms above the Ga vacancy surface and the As trimer surface (7B). The top atomic layers of the reconstruction are drawn as an overlay to assist in visualizing the adsorption sites.

FIGS. 8A and 8B show the potential energy surface for Ga and In adatoms above the Ga—As chain surface (8A) and the As—As chain surface (8B). The top atomic layers of the reconstruction are drawn as an overlay to assist in visualizing the adsorption and transition sites. The primary and secondary adsorption sites are A₁ and A₂, and the primary and secondary transition points are T and T′.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

Some embodiments of the current invention provide methods for the controlled formation of axial GaAs/InGaAs/GaAs heterostructures of varied thickness grown by selective area epitaxy (SAE) metal-organic chemical vapor deposition (MOCVD). This capability can be crucial for designing and realizing high-performance NP-based optoelectronic devices.

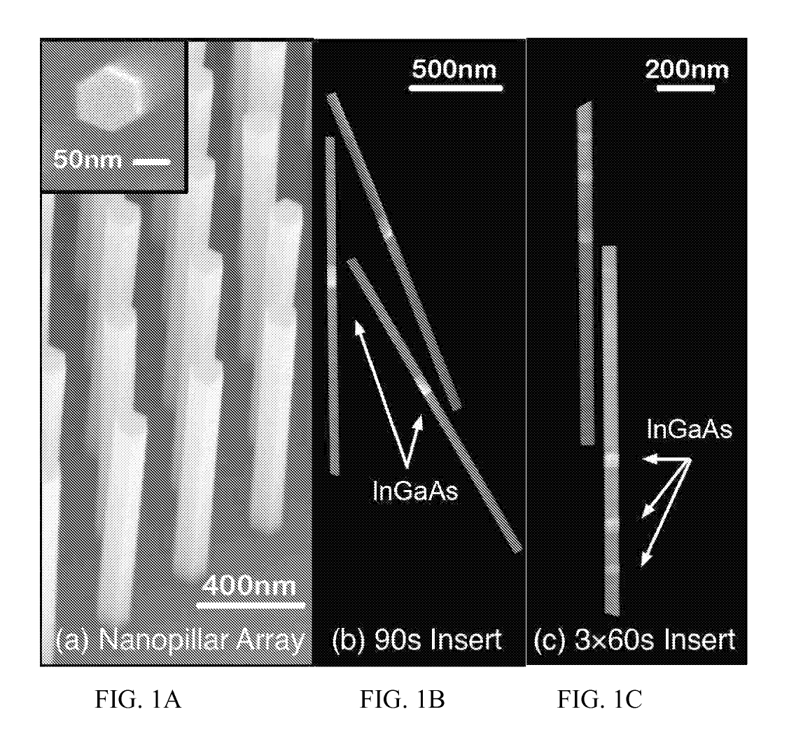

FIGS. 1A-1C shows some examples of axially hetero-structured nanowires according to an embodiment of the current invention. An axially hetero-structured nanowires according to an embodiment of the current invention includes a first segment comprising GaAs, and a second segment integral with said first comprising InₓGa₁₋ₓAs. The parameter x has a maximum value x-max within the second segment of at least 0.02 and less than 0.5. In some embodiments x-max within the second segment is at least 0.2 and less than 0.4. The value x-max can be x=0.4, for example, in some embodiments.

The term “nanowire” is intended to refer to nanostructures that include at least one of an electrically conducting or semiconducting material such that a longitudinal dimension is greater than an average lateral dimension. A ratio of the longitudinal dimension to the average lateral dimension can be defined as an aspect ratio of the nanowire. Nanowires according to the current invention can have aspect ratios of at least 2 in some embodiments, at least 5 in some embodiments, at least 10 in some embodiments, at least 100 in some embodiments, or even more in further embodiments. Nanowires can also sometimes be referred to as nanofibers. Nanowires according to embodiments of the current invention do not have to have circular cross-sectional shapes. For example, nanowires according to some embodiments of the current invention have hexagonal cross-sectional shapes. The lateral diameter of the nanowires is less than 200 nm in some embodiments, less than 100 nm in some embodiments, and less than 50 nm in some embodiments.

The term “nanopillar” is intended to include a nanowire that is at least one of integral with or attached to a substrate. This includes, but is not limited to, nanowires that are grown on a substrate such that they remain on the substrate after growth.

The term “segment” of the nanowire is referring to a distinguishable portion of the nanowire. FIG. 1B shows an example of three nanowires according to an embodiment of the current invention, each with two GaAs segments separated by an InGaAs segment. FIG. 1C shows an example of three nanowires according to an embodiment of the current invention, each with four GaAs segments in which adjacent segments are separated by one of the three InGaAs segments. The general concepts of the current invention are not limited to these particular examples. For example, a nanowire according to an embodiment of the current invention could have as few as two segments, one GaAs segment and one InGaAs segment. Other embodiments can include two GaAs segments and two InGaAs segments, which would be similar to the examples of FIG. 1B, but would be terminated with a further InGaAs segment. The general concepts of the current invention are not limited to any particular number of GaAs and InGaAs segments or to whether the nanowires are terminated with a GaAs segment or an InGaAs segment.

In some embodiments, the first segment consists essentially of the GaAs compound and the second segment consists essentially of InₓGa₁₋ₓAs. However, the broad concepts of the current invention are not limited to this particular embodiment. In other embodiments, it may be desirable to dope one or more of the segments. In some embodiments, the axially hetero-structured nanowire can be a strained crystal nanowire, for example. In some embodiments, the axially hetero-structured nanowire can have an effective cross-section diameter less than 200 nm and an axial length of at least 400 nm. The term effective cross-section diameter is intended to be an average and/or other conventional measure, particularly for slightly irregular and/or non-circular cross sections. For example, the “diameter” of a hexagonal nanowire can be defined as either the distance from vertex to vertex or from flat to flat. There is a simple mathematical relationship between the two methods. In some embodiments, the axially hetero-structured nanowire can have an effective cross-section diameter less than 100 nm and an axial length of at least 800 nm. In further embodiments, the axially hetero-structured nanowire can have an effective cross-section diameter less than 50 nm and an axial length of at least 1 μm. The broad concepts of the current invention are not limited to the particular length. Nanowires with lengths greater than 1 μm according to some embodiments of the current invention have been produced, and still longer nanowires can be produced.

In some embodiments of the current invention, nanowires with high uniformity along the axial direction can be produced. The axial direction is along a line running through the center of the nanowire in the long direction. In some embodiments, the effective cross-section diameter can be substantially uniform along an entire axial dimension, i.e., uniform to within ±10 nm. In further embodiments, the effective cross-section diameter can be substantially uniform along an entire axial dimension, i.e., uniform to within ±3 nm. In some embodiments, the axially hetero-structured nanowire can have a substantially uniform composition within each cross section along an entire axial direction to within ±2%. For example, in some embodiments, the GaAs and InGaAs segments do not have material coating the outer walls of the nanowire.

Another embodiment of the current invention is directed to a nanostructured semiconductor component that includes a GaAs (111)B substrate and a plurality of nanopillars that are integral with the substrate. FIG. 1A shows an example of a nanostructured semiconductor component according to an embodiment of the current invention. Each of the plurality of nanopillars includes a first segment comprising GaAs and a second segment integral with the first comprising InₓGa₁₋ₓAs. The parameter x has a maximum value x-max within the second segment that is at least 0.02 and less than 0.5. The plurality of nanopillars can be nanowires according to embodiments of the current invention. In some embodiments, the nanopillars can be removed to provide nanowires. However, it may be desirable for some applications to leave the nanowires attached to the substrate for use in devices in that form. The nanostructured semiconductor component can include other layers and/or doping, if desired. For example, if a SiO₂ mask layer is used in the production of the nanostructured semiconductor component, it can remain, if desired.

Another embodiment of the current invention is directed to a catalyst-free, selective-area metal-organic chemical vapor deposition method for producing nanostructures. The method includes providing a GaAs (111)B substrate that has a patterned layer on a surface to provide exposed regions for epitaxial growth of nanopillars. The method also includes exposing the substrate to tri-methyl-gallium and tertiary-butyl-arsine for a selected period of time to grow GaAs segments of the nanopillars on the exposed regions, and exposing the substrate and portions of nanopillars grown on it to tri-methyl-indium, tri-methyl-gallium and tertiary-butyl-arsine for a selected period of time to grow InₓGa₁₋ₓAs segments on the GaAs segments. During the growth of the InₓGa₁₋ₓAs segments, temperatures and pressures of tri-methyl-indium, tri-methyl-gallium and tertiary-butyl-arsine are selected such that the InₓGa₁₋ₓAs segments grow substantially exclusively in an axial direction of the nanopillars. The parameter x has a maximum value x-max within a respective InₓGa₁₋ₓAs segment of at least 0.02 and less than 0.5.

In catalyst-free growth, atoms in the vapor phase adsorb (bind to the surface) on all crystal facets of the nanopillar. When attempting to grow material B on top of material A, material B will adsorb (bind to the surface) and incorporate (become part of the crystal) on both the nanopillar side facets and the nanopillar top facet. All prior attempts at hetero-epitaxy resulted in formation of a complete shell of material B on material A.

Adsorption on all crystal facets is a natural part of nanopillar epitaxy (growth), and cannot be avoided, so to form of an axial heterostructure, incorporation on the side facets is suppressed while incorporation on the top facet is promoted. For an embodiment of the current invention, we have calculated and shown that under arsenic rich conditions, the surface reconstructions on the side facets and the top facet of GaAs change in precisely the way described. The side facets assume an arsenic-rich reconstruction which promotes increased diffusion of atoms up the sides, and towards the tip. Meanwhile the binding energy for indium becomes more competitive with gallium for the arsenic-rich reconstruction on the tip.

Another embodiment of the current invention is directed to a nanostructured semiconductor component produced according to a catalyst-free, selective-area metal-organic chemical vapor deposition method according to an embodiment of the current invention.

This growth method can be utilized to produce nanowires that can be used in nanowire-based photonics and electro-optic devices, for example. The precision control of nanowire position and diameter by selective-area epitaxy can allow for the engineering of the interaction between the three-dimensional structures and electro-magnetic radiation. Some applications that have been demonstrated by the inventors include continuous-wave photonic crystal lasers, and plasmonically enhanced photo-detectors. Other applications can include solar photo-voltaic cells, for example.

It is possible to form similar structures by growing thin films and etching nanopillars into the film using high resolution lithographic techniques. The bottom-up technique according to embodiments of the current invention can provide four distinct advantages over a top-down method:
Aspect ratio: When etching pillars, in the best case scenario, the resulting nanopillars are tapered from top to bottom with a few degree angle. Assuming a residual 2° taper, a two micron tall etched pillar will have a base with a diameter almost 140 nm in diameter wider than the top. In contrast, nanowires grown by selective-area epitaxy according to an embodiment of the current invention can have a negligible change in diameter from the top to the bottom, a few nanometers at most. This absence of taper can result directly in fabrication of high-Q photonic crystals.
InGaAs ternary composition: Thin film hetero-epitaxy between lattice-mismatched GaAs and InGaAs is severely limited in film thickness. There is an inverse relationship between the indium fraction and the allowed thickness of the InGaAs region. For this reason, the highest indium composition in thin film epitaxy is typically 15%, resulting in emission of photons with a wavelength of 1.04 μm, and the thicknesses are tens of nano-meters at most. In contrast, strain compensation in nanowires is much better, and arbitrary lengths of InGaAs can be grown with composition as high as 40%, having photon emission wavelengths up to 1.32 μm according to some embodiments of the current invention.
Reduced surface-states: Etching nanopillars results in pillar side facets with high roughness. The rough edges on the side walls act as non-radiative electron-hole recombination centers, reducing the optical efficiency of the device. In contrast, nanowire side facets are crystalline with atomic layer roughness. There is still surface recombination, but it is drastically reduced compared to etched nano-pillars. This is evident in the continuous-wave operation of the nano-lasers formed with this nanowire growth mode.
In-Situ passivation: When combined with shell growth of a third material, InGaP, having a higher bandgap than either GaAs or InGaAs, the electrons and holes are confined to the core of the nanopillar and surface recombination is dramatically reduced. The ability to grow these high bandgap shells immediately after the growth of the core nanopillar is a feature unique to bottom-up growth of nanopillars.

The following describes some examples according to embodiments of the current invention. The general concepts of the current invention are not limited to these particular examples.

### EXAMPLE 1

In the following examples, the axial GaAs/InGaAs/GaAs heterostructure NPs are grown on a patterned GaAs (111)B substrate via SAE. A SiO₂ growth mask is patterned into 200 μm square arrays of nanoholes (80 nm diameter, 300 nm pitch) using electron beam lithography and anisotropic plasma assisted etching. The NP samples, including InGaAs inserts (also called segments), are grown at 720° C. in a hydrogen environment at 60 Torr. The GaAs sections are grown using tri-methyl-gallium(TMGa) and tertiary-butyl-arsine(TBA) with a V-III ratio of 9. The precursor flow rates result in 0.5 Å/s equivalent planar growth rate on GaAs (001) substrates. To form the axial InGaAs inserts, tri-methyl-indium(TMIn) is introduced keeping TMGa unchanged at a gas flux ratio of 1:4 (TMIn:TMGa) and the V-III ratio is increased to 50. Thirty second growth interrupts are included before and after formation of each insert to adjust the TBA flux and allow time for the arsenic rich surface reconstructions to form. Three samples are studied including NPs with single inserts grown for 180 s and 90 s and NPs with triple inserts grown for 60 s each and separated by GaAs segments grown for 120 s. Resulting insert thickness and composition are analyzed below for all three samples. A plot of the 180 s insert is not shown due to space constraints.

FIG. 1A shows a 45° tilted scanning electron microscope (SEM) image of a representative NP ensemble with 85±5 nm diameter and lengths of 1.8±0.08 μm. The inset shows a top-down image of the pillar tip with {011⁻} side facets. For further microscopic analysis, these pillars are removed from the substrate and mechanically transferred to a copper grid. FIGS. 1B and 1C show high angle annular dark field (HAADF) scanning transmission electron micrographs (STEM) of multiple wires with single InGaAs 90 s and 3×60 s InGaAs inserts, respectively. The InGaAs inserts, which appear brighter compared to the, surrounding GaAs, have very similar dimensions and position along the length of the pillar. The length of inserts measured from multiple dark field STEM are 220±20 nm and 130±10 nm from the 180 s and 90 s growths, respectively. The 3×60 s inserts become progressively thicker from 36±4 nm to 53±4 nm and 62±6 nm. An immediate observation is that pillar segments, defined by the heterointerfaces, become increasingly longer for equivalent or shorter growth times. This observation indicates an increasing growth rate as described in more detail below.

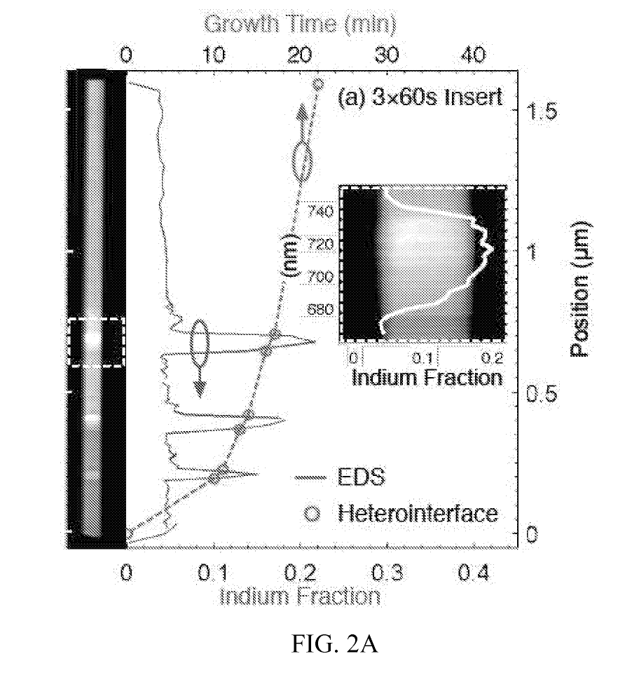

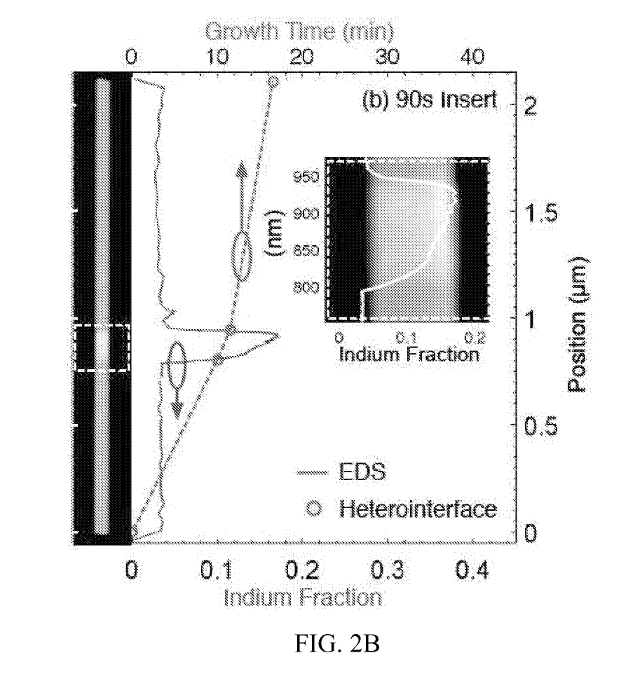

FIGS. 2A and 2B plot both In content and growth time versus position along a single representative 3×60 s and 90 s pillar, respectively. The pillar STEM image is shown to the left of each plot. The In content is measured using line scan energy dispersive x-ray spectroscopy (EDS) with a ˜1 nm spot size and 0.04 background noise levels. Peak In content in the InₓGa₁₋ₓAs alloy is x=0.21 and x=0.16 for the 180 s and 90s inserts, respectively. The three insets in the 3×60 s pillar have increasing In contents of x₁=0.13, x₂=0.16, x₃=0.19, which we suspect is caused by cumulative strain along pillar length allowing more In to incorporate in subsequent inserts. Spikes in In content correspond to the bright segments in the adjacent STEM. The insets show magnified views of the inserts enclosed by a dashed box to elucidate In content at each heterointerface. Both insets show an initial rise in In to ˜10% followed by a gradual increase to the respective peak value. We attribute the graded In:Ga at the bottom interface to In segregation as the growth front progresses (K. Muraki, S. Fukatsu, Y. Shiraki, and R. Ito, Appl. Phys. Lett., 61, 5 (1992)). The more abrupt In:Ga transition at the top interface in both wires is likely caused by strain-driven In:Ga intermixing which occurs once growth commences after the growth pause. The vertical position of each InGaAs/GaAs heterointerface (open circles) marks a distinct point of time in the growth recipe and allows calculation of growth rate. The slope of the dashed line connecting these markers approximates growth rate, which increases with pillar position.

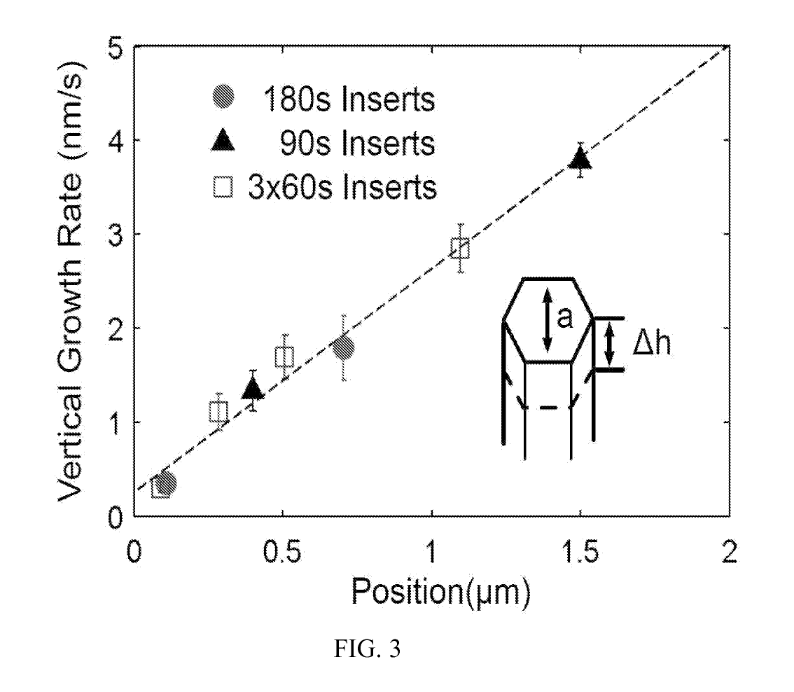

FIG. 3 shows the calculated growth rate as a function of the vertical position of the GaAs sections of the pillar, averaged over 5 wires from each sample. The dashed line is a linear fit to the data showing the vertical growth rate, Rₕ, increases with position in the pillar, h, as Rₕ=0.26 [nm/s]+2.38 [nm/s·μm]h . From Ikejiri, et al. (id.), we explain this dependence by considering the possible sources of adatoms contributing to vertical pillar growth. In equation 1 we define an infinitesimal volume at the pillar tip, a²Δh, which grows in a time Δt where a represents pillar diameter (see FIG. 3, inset). The three sources of adatoms include direct incorporation from the vapor at the pillar tip, capture and subsequent adatom diffusion along the {011⁻} NP sidewalls and capture on the SiO₂ mask area, (s²−a²), expressed in the three terms below.

a²Δh=[C₁a²+C₂4ha+C₃(s²−a²)]Δt (1)

The coefficients C₁, C₂ and C₃ account for the net effects of diffusion, adsorption and desorption as the adatoms encounter the crystal planes. When expressed as vertical growth rate, Rₕ, at position h along the pillar, equation (1) becomes

$${R}_{h} = \frac{Δ h}{Δ t} = [ {C}_{1} + {C}_{3} ( \frac{{s}^{2}}{{a}^{2}} - 1 ) ] + \frac{4 {C}_{2}}{a} h . \qquad ( 2 )$$

The term in square brackets varies with mask pitch, s, and pillar diameter, a, which remain constant for a given mask geometry assuming only vertical growth. The second term represents the vertical growth rate contribution from the pillar sidewalls.

The measured linear dependence of vertical growth rate on position reveals pillar sidewalls are the dominant source of adatoms driving mid-stage pillar growth for this pattern geometry. Adsorption directly from the vapor onto the pillar tip and the surrounding mask area are important effects at early stages of pillar formation but eventually the pillar sidewalls contribute the majority of adatoms to the growing pillar tip. A complete analysis of the effect of pillar diameter and pattern pitch on vertical growth rate is currently in press (Shapiro, et. al., In Press).

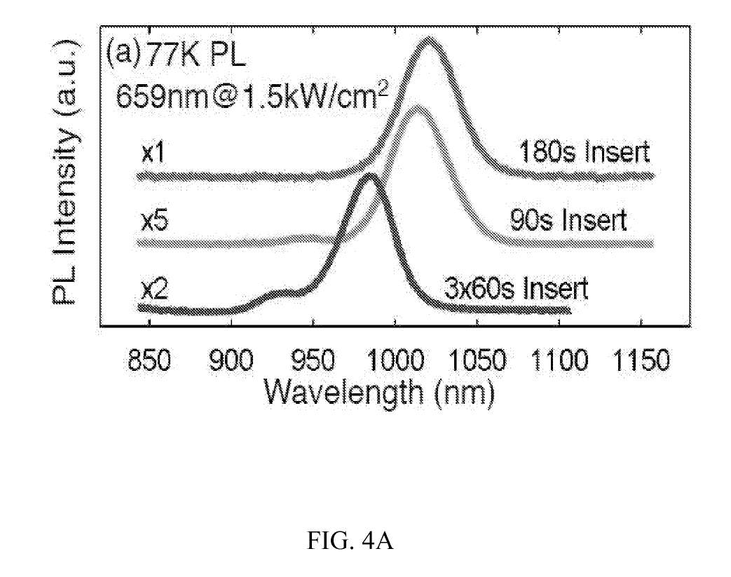

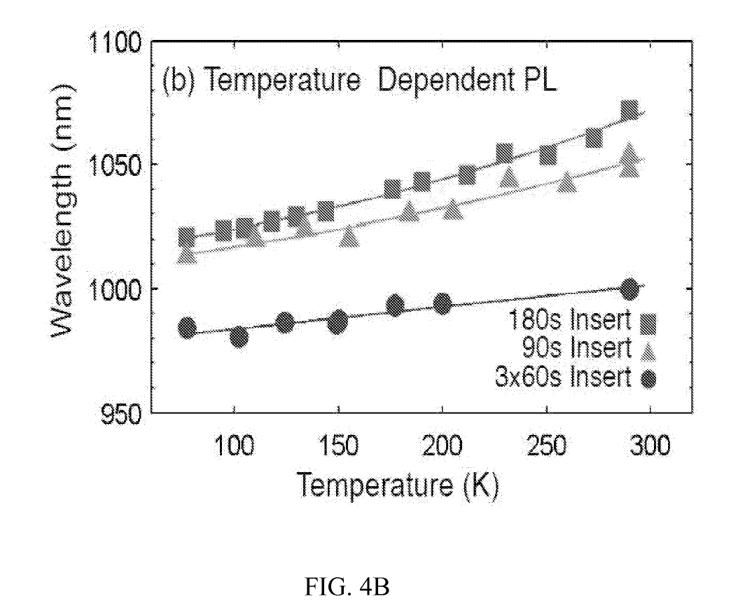

Indium content and crystal quality is further verified by temperature-dependent micro-photoluminesence (PL) of the samples with 180 s, 90 s and 60 s inserts using a 0.5 m focal length spectrometer and an InGaAs focal-plane-array detector. The 659 nm 0.5 mW diode pump laser is focused to ˜3 μm spot to excite an ensemble of ˜50 NPs. FIGS. 4A and 4B show 77K PL spectrum and PL peak wavelength versus temperature for all three samples. The 77K emission peaks at a wavelength of 1021 nm for the 180 s insert and 1013 nm for the 90 s insert. The 3×60 s inserts have an emission peak at 988 nm and a shoulder at 932 nm. The FWHM for all three samples is 70-80 nm at room temperature, decreasing to 35-40 nm at 77K. In all cases the PL emission is consistent with an In content of 0.15-0.2 using published formulas for InGaAs bandgap at 77K (Properties of Lattice-Matched and Strained Indium Gallium Arsenide, Pallab Bhattacharya, Data Review Vol 8, INSPEC (1993)). The slight blue shift from 180 s to 90 s inserts is consistent with a reduced In content. A large blue-shift from 90 s to 60 s inserts despite equivalent In content is likely caused by increased strain in the shorter inserts (C. Rivera, U. Jahn, T. Flissikowski, J. L. Pau, E. Munoz, and H. T. Grahn, Physical Review B, 75, 4 (2007)). In FIG. 4B, the temperature dependence of the peak wavelength has less curvature as inserts become shorter and approaches a linear relationship, also in agreement with strained material (D. E. Wohlert, S. T. Chou, A. C. Chen, K. Y. Cheng, and K. C. Hsieh, Applied Physics Letters, 68, 17 (1996)).

In conclusion, GaAs/InGaAs/GaAs axial double heterostructures embedded in GaAs patterned NPs were grown by SAE MOCVD according to an embodiment of the current invention. Single pillars were studied by TEM and EDS to show the control of insert thickness and a variation of In content along the growth direction of the pillars. Examination of growth rates using the heterostructure interfaces as markers reveals a linear dependence of pillar growth rate on pillar height indicating that the entire sidewall of the pillar plays a role in mid-stage pillar growth. However, the general concepts of the current invention are not limited by whether these equations and theoretical explanations are correct. These types of quantum structures in single semiconductor nanopillars have the potential for application in electronics and optoelectronics.

### EXAMPLE 2

NP synthesis by catalyst-free selective area metal-organic chemical vapor deposition (SA-MOCVD) is a growth technique for forming large arrays of uniform NPs in lithographically defined locations. The precision with which the NPs can be positioned can be utilized for fabrication of photonic crystals or electronic devices requiring precision lithography and alignment.

The absence of a metal particle to catalyze growth means that atoms adsorb directly onto the crystal surfaces from the vapor, and the resulting crystal shape is controlled in part by minimization of the total surface free energy [Keitaro Ikejiri, Takuya Sato, Hiroatsu Yoshida, Kenji Hiruma, Junichi Motohisa, Shinjiroh Hara, and Takashi Fukui, Nanotechnology, 19, 26265604(2008)]. GaAs nanopillars grow in the [111] direction, and have hexagonal symmetry with side facets composed of the six (011⁻) planes. Atoms from the vapor adsorb on all facets of the NP and then diffuse to the (111) surface at the tip where they incorporate. The polar (111) surface has a higher surface energy than the stoichiometric {011} family, making the observed crystal shape thermodynamically favorable. However, the vertical growth of nanopillars has a strong temperature dependence, so adatom kinetics and surface reaction rates must also play an important role in epitaxy.

Heterostructure formation is a necessary capability to master in catalyst-free NP synthesis in order to create efficient optical devices [Ritesh Agarwal, Small, 4, 111872-1893(2008)]. Core-shell hetero-structures have been studied in a variety of material systems, but axial hetero-structure formation has been elusive in this growth mode. When a new atomic species is introduced, the surface energetics must promote incorporation of the new species on the top (111) surface while simultaneously suppressing nucleation on the side-walls.

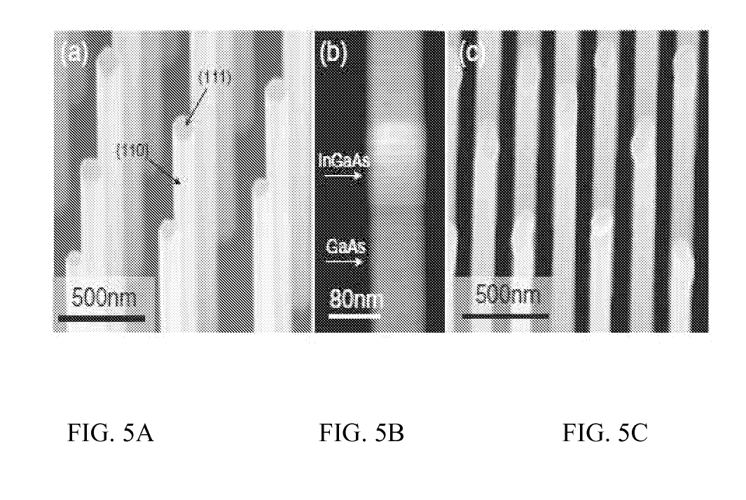

Despite this challenge, axial InGaAs segments of varying composition and thickness were recently demonstrated in GaAs catalyst free NPs grown by SA-MOCVD as described above. High As flow rates were used to promote incorporation of In on the NP tip with negligible shell growth. At the lower As flow rates typically used for GaAs NP homoepitaxy, In is not selective to the (111) surface, and instead nucleates on the side-walls, deforming the crystal facets. FIG. 5A shows a scanning electron micrograph (SEM) of NPs formed by SA-MOCVD with axial InGaAs inserts formed at high As flow rates. The vertical side-walls and hexagonal symmetry are evident. FIG. 5B shows a dark field scanning transmission electron micrograph (STEM) of the same pillars revealing the axial InGaAs segment. In contrast, FIG. 5C shows pillars terminated with InGaAs at low As flow rates. These pillars have deformed crystal facets due to In nucleation on the side-walls. This tendency for In to bond to all available crystal surfaces has also been reported by [H. Paetzelt, V. Gottschalch, J. Bauer, G. Benndorf, and G. Wagner, Journal of Crystal Growth, 310, 235093-5097(2008)].

To investigate possible reasons for the observed difference in behavior between In and Ga during nanopillar epitaxy, we present a theoretical investigation of the potential energy surface (PES) for Ga and In tracer adatoms situated above the stable (111)A and (110) surfaces of a NP. The stable surfaces at both high and low As chemical potential are investigated to parallel the experimental conditions of high and low As flow rates. The technique of calculating a PES has been applied by numerous researchers as a tool for studying diffusion, adsorption and desorption and for understanding epitaxy on crystal surfaces.

In this section the diffusion barriers and binding energies of In and Ga adatoms are computed and compared to determine the mobility of each species on the surface, and to glean insight into the physical processes that determine the preferred facet for hetero-epitaxy. The surfaces under consideration are pure GaAs, therefore the calculations are relevant to nucleation of the first layer of InGaAs on a free standing GaAs NP.

Computational methods are discussed first, followed by a description of the calculations and their results. We conclude with a discussion and interpretation of the results.

### Computational Methods

A potential energy surface (PES) calculation for a Ga or In adatom begins with the computation of the equilibrium surface geometry without the adatom.

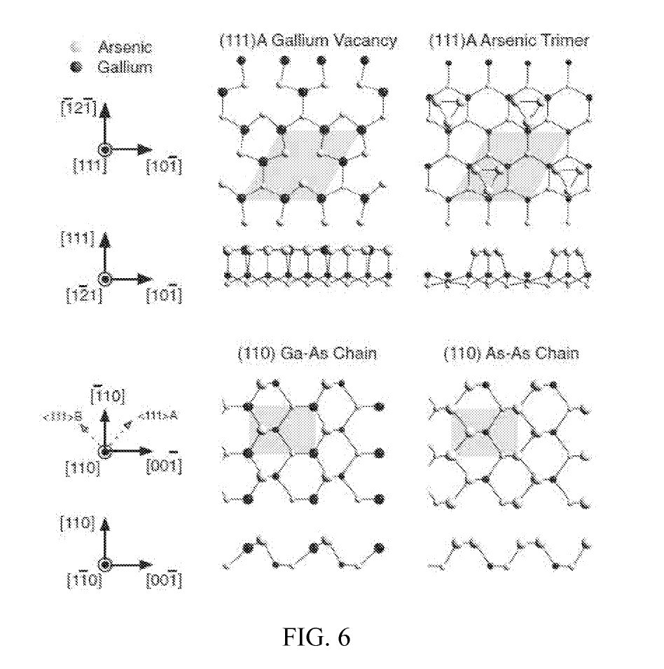

The surfaces under consideration are the (111)A and (110) surfaces. The top and side views of each surface are shown in FIG. 6. The NP side-walls are actually the six (1⁻10) surfaces, but these are structurally identical to the (110) surface under investigation. The (111)A Ga vacancy and (110) Ga—As chain are stable under As-poor conditions, when the As chemical potential is low. The (111)A As trimer and (110) As—As chain are stable under As-rich conditions when the As chemical potential is high [N. Moll, A. Kley, E. Pehlke, and M. Scheffler, Phys. Rev. B, 54, 128844-8855(1996)]

The (111) surfaces have a 2×2 unit cell indicated by a shaded parallelogram, and the (110) surfaces have a 1×1 unit cell indicated by a shaded rectangle. In our calculations the (111) slabs are 9 mono-layers thick and the (110) slabs are 8 mono-layers thick. All surfaces are iteratively relaxed, keeping the bottom three mono-layers fixed, until residual atomic forces are <0.02 eV A°. After the relaxed surface is computed, the PES can be computed by finding the total energy of the surface with a single adatom at different points above the surface.

The total energy of the surface with an additional Ga or In adatom is computed using a larger super cell to suppress interaction between the adsorbates. The top layers of the slab and the adatom are allowed to relax, but the adatom coordinates are fixed perpendicular to the [111] direction (the adatom is fixed in the x-y plane and allowed to relax in z). The two (111) surfaces have 3-fold rotational symmetry, and each rotationally symmetric slice has a mirror symmetry such that only 8 points are sampled in a triangle above the 2×2 unit cell. The calculated energies are reflected, rotated twice through 120° and mapped to a rectilinear grid using a cubic interpolation to generate a PES for the adatom of interest. The energy zero-point is chosen to be the total energy of the relaxed, reconstructed surface plus the total energy of an isolated atom of In or Ga.

A similar process is used to calculate the PES for the (110) surfaces, but these surfaces are simpler because they only have a mirror symmetry. The lowest energy site for these surfaces, however, does not lie in a region of high symmetry. To find the true potential minimum, the adatom is placed at the site with the lowest energy and allowed to relax without positional constraints.

Calculations are performed within the framework of density-functional theory (DFT) as implemented in the software package FHI-AIMS [Volker Blum, Ralf Gehrke, Felix Hanke, Paula Havu, Ville Havu, Xinguo Ren, Karsten Reuter, and Matthias Scheffler, Computer Physics Communications, 180, 112175-2196(2009)], which uses numeric atom centered orbitals for its basis set and includes a relativistic correction for heavy atoms (Z>30). The Perdew-Burke-Ernzerhof (PBE) parameterization of the generalized gradient approximation is used for the exchange correlation functional. Approximately 16 layers of vacuum and 64 equivalent k-points in the 1×1 unit cell are specified. Convergence of the energy difference between the maximum and minimum on the PES is confirmed for the k-points, slab thickness, vacuum layers and super-cell size for the Ga vacancy and the Ga—As chain surface.

Calculations were performed using the FHI-AIMS pre-defined “light” setting. In the “light” setting, each atom has radial basis functions of s,p and d character with an overall cutoff radius of 5 A° (A°: Angstrom), and a local Hartree potential expansion up to l=4. Key results were tested for convergence by calculation with the pre-defined “tight” setting. In the “tight” setting each atom has a finer integration grid, an additional f-like basis function, an overall cutoff radius of 6 A°, and a local Hartree potential expansion up to l=6. The binding energy difference for a Ga adatom at the maximum and minimum of the Ga vacancy PES is 1.056 eV using “light” and 1.051 eV using “tight”. Calculations are therefore considered to be well converged.

### Results

The potential energy surfaces for In and Ga adatoms above each surface reconstruction are presented in this section. The binding energies at adsorption sites, Aᵢ, transition points, T and T′, primary diffusion barriers, E_{D}=T−A₁, and secondary diffusion barriers, E′_{D}=T′−A₁, for In and Ga above each surface are collected in Table I for the GaAs (111)A surface and in Table II for the GaAs(110) surface. The main results are that under As-rich conditions the diffusion barriers decrease, and the binding energy for In in the A₁ adsorption site is more competitive with Ga.

TABLE 1
Calculated parameters for the (111)A surface. Diffusion
barrier E_{D}, minimum potential energy A₁, secondary minimum
potential energy A₂, and transition points T and T′ of In and Ga
adatoms. All values are in electronvolts (eV).

| Surface | Adatom | E_{D} | E′_{D} | A₁ | A₂ | T | T′ |
|---|---|---|---|---|---|---|---|
| Ga vacancy | Ga | 1.06 | 1.14 | −2.87 | −2.21 | −1.81 | −1.73 |
| | In | 0.92 | 1.0 | −2.65 | −2.06 | −1.73 | −1.65 |
| As trimer | Ga | 0.27 | — | −7.10 | — | −6.83 | — |
| | In | 0.26 | — | −6.99 | −6.88 | −6.73 | — |

TABLE II
Calculated parameters for the (110) surface. Diffusion
barrier E_{D}, minimum potential energy A₁, secondary minimum
potential energy A₂, and transition points T and T′ of In and Ga
adatoms. All values are in electronvolts (eV).

| Surface | Adatom | E_{D} | E′_{D} | A₁ | A₂ | T | T′ |
|---|---|---|---|---|---|---|---|
| Ga—As chain | Ga | 0.22 | 0.57 | −2.35 | — | −2.13 | −1.78 |
| | In | 0.23 | 0.52 | −2.23 | — | −2.00 | −1.71 |
| As—As chain | Ga | 0.15 | 0.31 | −2.50 | −2.45 | −2.35 | −2.19 |
| | In | 0.12 | 0.38 | −2.49 | −2.44 | −2.37 | −2.11 |

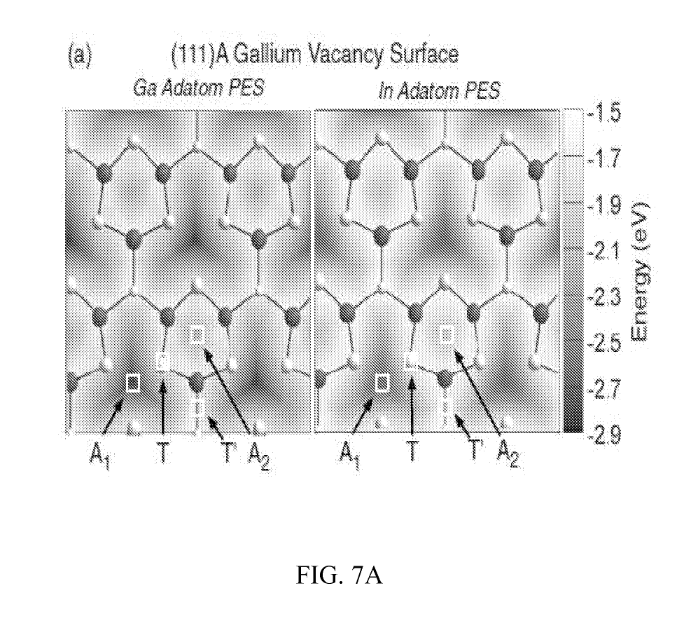

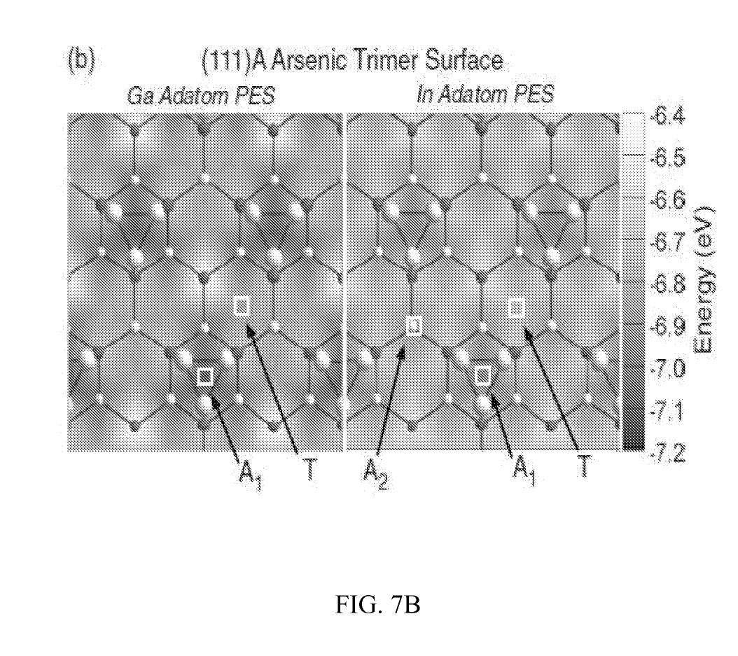

Comparing In and Ga adatoms above the Ga vacancy surface, FIG. 7A, the PES are qualitatively similar, with a deep minimum at the vacancy site A₁, and a secondary minimum at the site A₂, above third layer As atoms. The transition points, T and T′, are saddle points of the PES that are crossed when hopping between adsorption sites, but the deep potential minimum makes atoms adsorbed onto this surface essentially immobile.

If atoms are able to overcome the deep potential well, diffusion can occur by two possible pathways. Either the adatom hops directly between A₁ sites over the transition point T′, or it crosses over the point T into the secondary site A₂, and then rapidly hops back into an adjacent A₁ site. At typical growth temperatures of ˜1000 K, diffusion between A₁ sites by way of A₂ is fast enough to dominate the diffusion path. The diffusion barrier, E_{D}, reported in Tables I and II is the barrier to hop from A₁ to A₂.

Ga atoms are less mobile than In on this surface with a diffusion barrier 140 meV higher than In regardless of the path taken. The binding energy of a Ga adatom at A₁ is 220 meV larger than for In, suggesting that Ga adatoms will be adsorbed preferentially over In adatoms. This calculation agrees with the observation that In floats to the surface when forming the NP hetero-interface\cite {shapiro:243102}.

The PES for a Ga adatom above the Ga vacancy reconstruction was previously calculated by Taguchi et al. [Akihito Taguchi, Kenji Shiraishi, and Tomonori Ito, Physical Review B, 60, 1611509-11513(1999)]; however, our results are significantly different. In that work, contrary to expectations, they found the potential energy minimum was not in the lattice site vacated by the Ga atom, but at adjacent interstitial locations with diffusion energy barriers of ˜0.4 eV. Our calculations, in contrast, show a deep potential minimum at the vacant lattice site with diffusion barriers ˜1.0 eV. We are unable to explain the discrepancies between the two calculations, however, the Taguchi et. al. acknowledge that the vacant Ga site should be more stable according to calculations based on the interatomic potential. In light of the conflicting results, we carefully checked our energy calculations and algorithms for generating the PES, which exploit the surface symmetry, and are unable to find errors in our methods.

The As trimer PES for In and Ga adatoms are presented in FIG. 7B. The As trimer surface is the stable reconstruction appearing in As-rich environments, and is characterized by the presence of an As trimer to satisfy electron counting. The PES for both In and Ga adatoms have potential energy minimum A₁ at the center of the As trimer, and a diffusion barrier height of 260-270 meV. The PES for an In adatom also has a secondary minimum, A₂, above one of the second layer As atoms that can potentially slow the diffusion for In. The difference in binding energy between Ga and In is only 110 meV for the As trimer surface, compared to 220 meV for the Ga vacancy surface. Indium adatoms will have a higher probability of incorporation on this surface compared to the Ga vacancy surface because of the equivalent diffusion coefficients and more competitive binding energy.

The sidewalls of a pure zinc-blende NP are either the relaxed Ga—As chain or the As—As chain, as rendered in FIG. 6. The Ga—As chain surface is named for the chain of Ga and As atoms that run along the surface. When relaxed, the top layer Ga atom moves down so that the three bonds all lie in the same plane, and the As atom bonds approach ninety degrees. The surface resembles a trench-ridge structure.

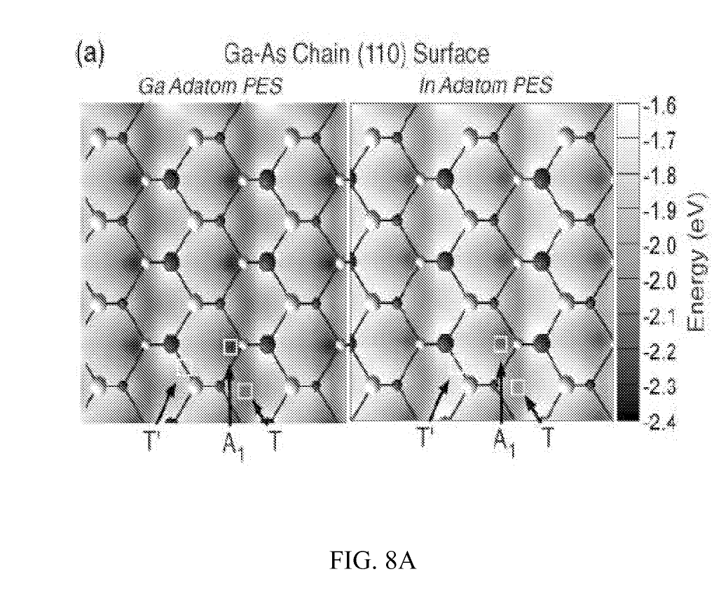

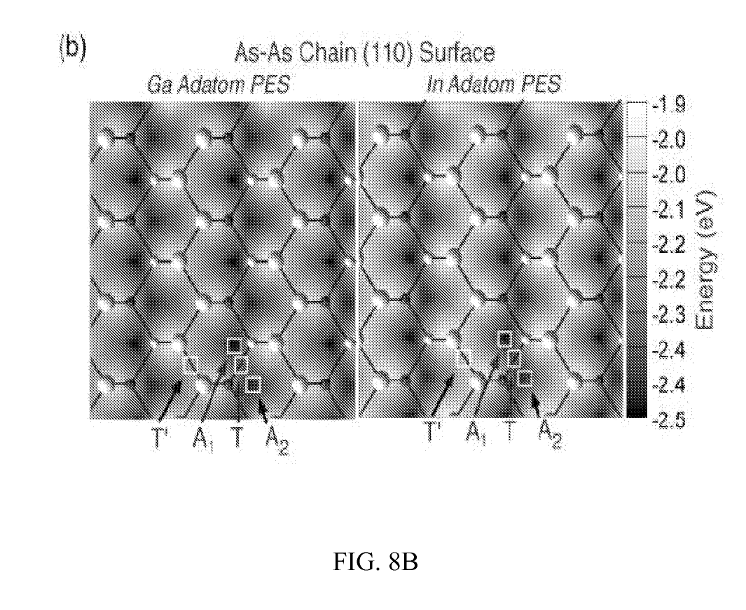

The Ga—As chain PES, shown in FIG. 8A, has an adsorption site in the trench adjacent to the As atom. The primary transition point also lies in the trench, but it is adjacent to the Ga atom. The diffusion barrier is comparable for In and Ga at 220 to 230 meV, suggesting that In and Ga have similar diffusion lengths on (110). In reality, the diffusion coefficient will vary with the vibrational free-energy of the atom, and change the diffusion barrier by as much as a few hundred meV [Ulrike Kurpick, Abdelkader Kara, and Talat, Physical Review Letters, 78, 61086-1089(1997)]. Even with this effect, diffusion is much faster on this surface than on the (111)A Ga vacancy surface, and it is highly anisotropic with atoms shuttled along the trenches.

In As-rich environments, the top layer Ga adatom is replaced by an As atom creating an As—As chain. Like the Ga—As chain, the As—As chain PES has an adsorption site in the trench adjacent to the As atom, FIG. 8B, but a second absorption site, A₂, appears in the trench adjacent to the Ga atom. The diffusion barrier for travel along the trench is reduced to 150 meV and 120 meV for Ga and In adatoms respectively. Twice as many barriers must be crossed to travel the same distance, but the lower diffusion barriers will result in significantly faster diffusion for both species.

Because the chains of the {110} surfaces are oriented at a 45° angle to the [111] direction, adatoms are shuttled up the trenches at an angle to the NP growth direction. At some point, adatoms must hop over the ridge into an adjacent trench to continue their diffusion towards the tip. The secondary diffusion barrier E′_{D} is the barrier to cross the ridge from the primary adsorption site, A₁, over the secondary transition point T′. The As—As chain has a lower E′_{D} than the Ga—As chain by 260 meV and 140 meV for Ga and In respectively. The As—As chain has lower diffusion barriers than the Ga—As chain both along the trench and over the ridge.

### Discussion

Calculations were performed to provide a physical explanation for why As-rich conditions are required for formation of GaAs/InGaAs axial heterostructures in (111) oriented catalyst free NPs. We believe that the high As chemical potential results in surface reconstructions on the NP that promote In incorporation on the (111) NP tip, and simultaneously increase diffusion, and thus mass-transfer, of In adatoms along the {110} NP side-walls.

The calculations reported in this section support the hypothesis that the (111) As trimer surface, stable at high As chemical potential, is desirable for higher rates of In incorporation for two reasons. First, the difference in binding energy between Ga and In adatoms in the A₁ adsorption site is reduced from 220 meV on the Ga vacancy surface to 110 meV on the As trimer surface. This reduction means that In adatoms compete more effectively with Ga and have a higher probability incorporating into the crystal. Second the diffusion barriers, E_{D} are comparable for both Ga and In adatoms on the As trimer surface, yet the diffusion coefficient of In is roughly two orders of magnitude larger on the Ga vacancy surface at typical growth temperatures of ˜1000 K. On the Ga vacancy surface, In adatoms will diffuse more quickly than Ga and desorb more readily from the small (111) surface at the tip of the pillar. The resulting chemical environment of adsorbates at the pillar tip will be richer in Ga than in the surrounding vapor. In contrast, the comparable diffusion barriers of both Ga and In on the As trimer surface will result in a concentration of adsorbates representative of the concentration in the surrounding vapor. The two reasons cited explain why In adatoms incorporate more efficiently on the (111) surface at high As chemical potential.

At high As chemical potential the diffusion length of Ga and In adatoms on the (110) side-walls increases. The As—As chain surface, with lower diffusion barriers both in the trenches and over the ridges is more efficient at shuttling adatoms to the NP tip. Upon arrival at the tip, In is then more likely to incorporate in the presence of an As trimer surface.

In conclusion, the PES for tracer In and Ga adatoms above stable surface reconstructions of GaAs (111)A and (110) are calculated. The binding energy of In is more competitive with Ga under As-rich conditions (high As chemical potential) on the (111)A As-trimer surface, and so it has more opportunity for incorporation into the lattice. Also at high As chemical potential, the NP (110) side-wall has lower diffusion barriers, and so the mass-transfer rate of atoms to the tip increases. The combined effects of higher mobility and more competitive binding energy indicates that formation of the (111)A As trimer surface and the (110) As—As chain under As-rich conditions can promote formation of axial GaAs/InGaAs hetero-interfaces during nanopillar growth. However, the invention is not limited to the correctness above theoretical explanations.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

We claim:

1. An axially hetero-structured nanowire, comprising:
a first segment comprising GaAs; and
a second segment integral with said first comprising InₓGa₁₋ₓAs,
wherein x has a maximum value x-max within said second segment, and
wherein said maximum value x-max within said second segment is at least 0.02 and less than 0.5.

2. An axially hetero-structured nanowire according to claim 1, wherein x-max within said second segment is at least 0.2 and less than 0.4.

3. An axially hetero-structured nanowire according to claim 1, wherein said first segment consists essentially of said GaAs compound and said second segment consists essentially of said InₓGa₁₋ₓAs.

4. An axially hetero-structured nanowire according to claim 3, wherein said axially hetero-structured nanowire is a strained crystal nanowire.

5. An axially hetero-structured nanowire according to claim 1, wherein said axially hetero-structured nanowire has an effective cross-section diameter less than 200 nm and an axial length of at least 400 nm.

6. An axially hetero-structured nanowire according to claim 1, wherein said axially hetero-structured nanowire has an effective cross-section diameter less than 100 nm and an axial length of at least 800 nm.

7. An axially hetero-structured nanowire according to claim 1, wherein said axially hetero-structured nanowire has an effective cross-section diameter less than 50 nm and an axial length of at least 1 μm.

8. An axially hetero-structured nanowire according to claim 5, wherein said effective cross-section diameter is substantially uniform along an entire axial dimension to within ±10 nm.

9. An axially hetero-structured nanowire according to claim 5, wherein said effective cross-section diameter is substantially uniform along an entire axial direction to within ±3 nm.

10. An axially hetero-structured nanowire according to claim 1, wherein said axially hetero-structured nanowire has a substantially uniform composition within each cross section along an entire axial direction to within ±2%.

11. An axially hetero-structured nanowire according to claim 1, further comprising:
a plurality of segments comprising GaAs; and
a plurality of segments comprising InₓGa₁₋ₓAs,
wherein adjacent segments comprising GaAs have a segment comprising InₓGa₁₋ₓAs integrally formed therebetween, and
wherein adjacent segments comprising InₓGa₁₋ₓAs have a segment comprising GaAs integrally formed therebetween.

12. A nanostructured semiconductor component, comprising:
a GaAs (111)B substrate; and
a plurality of nanopillars integral with said substrate at an end thereof,
wherein each of said plurality of nanopillars comprises:
a first segment comprising GaAs, and
a second segment integral with said first comprising InₓGa₁₋ₓAs,
wherein x has a maximum value x-max within said second segment, and
wherein said maximum value x-max within said second segment is at least 0.02 and less than 0.5.

13. A nanostructured semiconductor component according to claim 12, wherein x-max within said second segment is at least 0.2 and less than 0.4.

14. A nanostructured semiconductor component according to claim 12, wherein said first segment consists essentially of said GaAs compound and said second segment consists essentially of said InₓGa₁₋ₓAs.

15. A nanostructured semiconductor component according to claim 14, wherein each of said plurality of nanopillars is a strained crystal nanopillar.

16. A nanostructured semiconductor component according to claim 12, wherein each said plurality of nanopillars has an effective cross-sectional diameter that is less than 200 nm and an axial length of at least 400 nm.

17. A nanostructured semiconductor component according to claim 12, wherein each of said plurality of nanopillars has an effective cross-section diameter that is less than 100 nm and an axial length of at least 800 nm.

18. A nanostructured semiconductor component according to claim 12, wherein each of said plurality of nanopillars has an effective cross-section diameter less than 50 nm and an axial length of at least 1 μm.

19. A nanostructured semiconductor component according to claim 16, wherein said effective cross-section diameter is substantially uniform along an entire axial dimension to within ±10 nm.

20. A nanostructured semiconductor component according to claim 16, wherein said effective cross-section diameter is substantially uniform along an entire axial direction to within ±3 nm.

21. A nanostructured semiconductor component according to claim 12, wherein each of said plurality of nanopillars has a substantially uniform composition within each cross section along an entire axial direction to within ±2%.

22. A catalyst-free, selective-area metal-organic chemical vapor deposition method for producing nanostructures, comprising:
providing a GaAs (111)B substrate comprising a patterned layer on a surface thereof to provide exposed regions for epitaxial growth of nanopillars; and
exposing said substrate to tri-methyl-gallium and tertiary-butyl-arsine for a selected period of time to grow GaAs segments of said nanopillars on said exposed regions;
exposing said substrate and portions of nanopillars grown thereon to tri-methyl-indium, tri-methyl-gallium and tertiary-butyl-arsine for a selected period of time to grow InₓGa₁₋ₓAs segments on said GaAs segments,
wherein, during said growth of said InₓGa₁₋ₓAs segments, temperatures and pressures of tri-methyl-indium, tri-methyl-gallium and tertiary-butyl-arsine are selected such that the InₓGa₁₋ₓAs segments grow substantially exclusively in an axial direction of said nanopillars,
wherein x has a maximum value x-max within a respective InₓGa₁₋ₓAs segment, and
wherein said maximum value x-max is at least 0.02 and less than 0.5.

23. A nanostructured semiconductor component produced according to the method of claim 22.
